(19) United States
(12) Patent Application Publication
(10) Pub. No.: US 2012/0241773 A1
(43) Pub. Date: Sep. 27, 2012

(54) LED BAR MODULE WITH GOOD HEAT DISSIPATION EFFICIENCY

(75) Inventors: YU-FEN CHANG, Hukou (TW); TE-WEN KUO, Hukou (TW)

(73) Assignee: ADVANCED OPTOELECTRONIC TECHNOLOGY, INC., Hsinchu Hsien (TW)

(21) Appl. No.: 13/303,169

(22) Filed: Nov. 23, 2011

(30) Foreign Application Priority Data
Mar. 22, 2011 (CN) 201110069294.X

(51) Int. Cl. H01L 33/60

(52) U.S. Cl. 257/88; 257/E33.06

(57) ABSTRACT

An LED bar module includes a lengthwise base and a number of LED chips. The lengthwise base includes a metal layer, a metal circuit layer, and an insulated layer between the metal layer and the metal circuit layer. The insulated layer has a groove in a central thereof to expose a part of the metal layer. The LED chips are placed in the groove and directly contact the exposed part of the metal layer. The metal circuit layer has two connecting portions electrically connecting with the LED chips. The LED chips are arranged in a line which is located between and juxtaposed with the two connecting portions of the metal circuit layer.

### BACKGROUND

1. Technical Field

The present disclosure relates to LED illumination devices, and particularly to an LED bar module with good heat dissipation efficiency.

2. Description of Related Art

Light emitting diodes (LEDs) have many advantages, such as high luminosity, low operational voltage, low power consumption, compatibility with integrated circuits, easy driving, long-term reliability, and environmental friendliness; thus, LEDs have been widely promoted as a light source.

However, there are still some problems with the LEDs, especially in the heat dissipation thereof. The higher the power that the LEDs consume, the more heat the LEDs produce. It is also much more difficult to dissipate heat generated by a small LED.

As well, a typical LED bar module contains the problem of heat dissipation, limiting the application thereof in daily life. High efficiency of heat dissipation for an LED bar module is not available yet.

What is needed therefore, is an LED bar module which can ameliorate the described limitations.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a top view of an LED bar module in accordance with a first embodiment.

FIG. 2 is a schematic, cross-sectional view of the LED bar module in FIG. 1, taking along line II-II.

FIGS. 3-9 are schematic, cross-sectional views illustrating steps of a method for manufacturing the LED bar module in FIG. 1.

### DETAILED DESCRIPTION

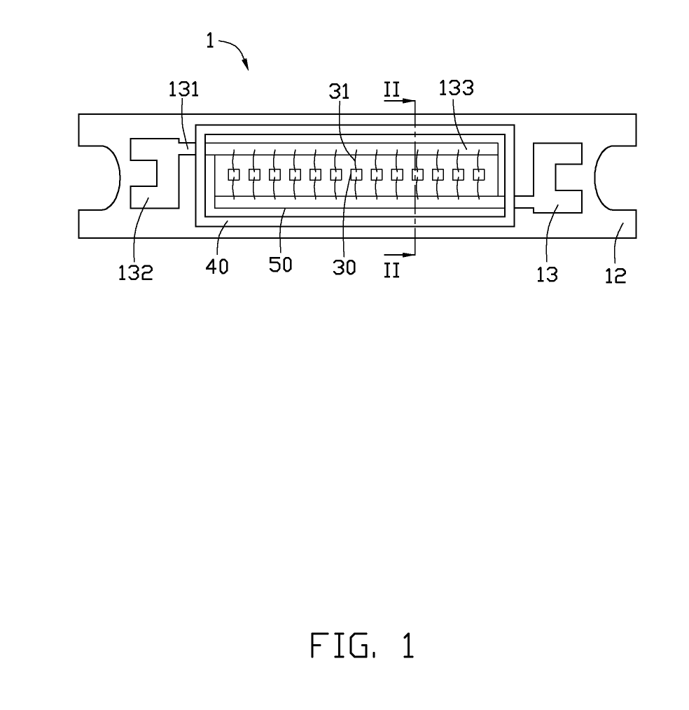

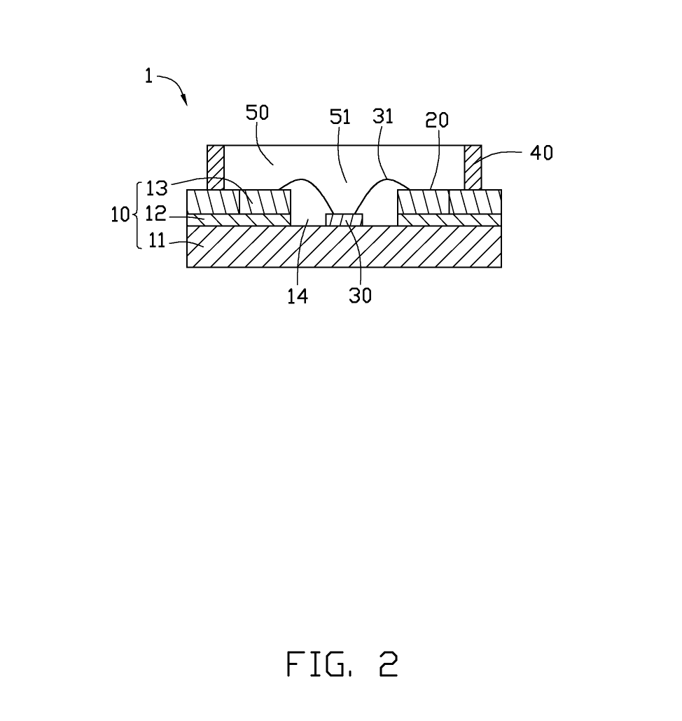

Referring to FIGS. 1 and 2, an LED bar module 1 in accordance with an embodiment includes a lengthwise base 10, a number of LED chips 30 mounted on the base 10, a reflecting wall 40 surrounding the LED chips 30, and an encapsulation 50 encapsulating the LED chips 30 therein.

The lengthwise base 10 has a metal layer 11, a metal circuit layer 13, and an insulated layer 12 between the metal layer 11 and the metal circuit layer 13. The metal layer 11 and the insulated layer 12 are both flat. A groove 14 is defined in a central of the insulated layer 12. The groove 14 extends through the insulated layer 12 to expose a part of a top surface of the metal layer 11. The LED chips 30 are received in the groove 14 and spaced from each other, so the groove 14 can function as a receiving space for receiving the LED chips 30 therein. The LED chips 30 directly contact the exposed part of the top surface of the metal layer 11.

The metal circuit layer 13 includes two opposite connecting portions 131; each connecting portion 131 includes a U-shaped bonding part 132 and an elongated strip 133 connecting the bonding part 132. The bonding parts 132 of the two connecting portions 131 are symmetrically located at two opposite ends of the base 10, and the elongated strips 133 of the two connecting portions 131 face and are parallel to each other. The elongated strips 133 are between the bonding parts 132. The bonding parts 132 are configured for facilitating transmitting electrical power and signals from an external apparatus (not shown) to the LED chips 30.

The metal layer 11 and the metal circuit layer 13 are made of copper with good flexibility. A thickness of the metal circuit layer 13 is less than that of the metal layer 11. In the present embodiment, the thickness of the metal layer 11 ranges from 0.2 mm to 0.3 mm, the thickness of the metal circuit layer 13 ranges from 0.15 mm to 0.2 mm, and the thickness of the insulated layer 12 is about 0.1 mm. In other embodiments, anti-oxidation materials, such as Ni, Ag can be spread on the metal circuit layer 13 and the exposed part of the top surface of the metal layer 11 to protect them from oxidation.

The LED chips 30 are attached on the metal layer 11 and received in the groove 14. In the present embodiment, the LED chips 30 are arranged in a line between the two elongated strips 133 in a juxtaposed manner. Two electrodes (not shown) of each LED chip 30 are respectively connected to the two strips 133 by metal wires 31. The LED chips 30 are directly mounted on the metal layer 11 of the base 10, so heat from the LED chips 30 is effectively dissipated by the metal layer 11 away from the LED chips 30, whereby heat-dissipation efficiency of the LED bar module 1 is optimized and lifespan of the LED chips 30 can be extended.

The reflecting wall 40 is located on the metal circuit layer 13 of the base 10 to surround the groove 14. The reflecting wall 40 may be rectangular, elliptical, circular, etc. In the present embodiment, the reflecting wall 40 is rectangular and has four side walls substantially perpendicular to the base 10, for reflecting light from the LED chips 30.

The encapsulation 50 is filled in the reflecting wall 40 to encapsulate the LED chips 30 and the two strips 133 therein, which are extended within the reflecting wall 40. In the present embodiment, a top of the encapsulation 50 is coplanar with a top of the reflecting wall 40. Alternatively, the top of the encapsulation 50 may be a concave surface or a convex surface to modulate the light field of the LED chips 30.

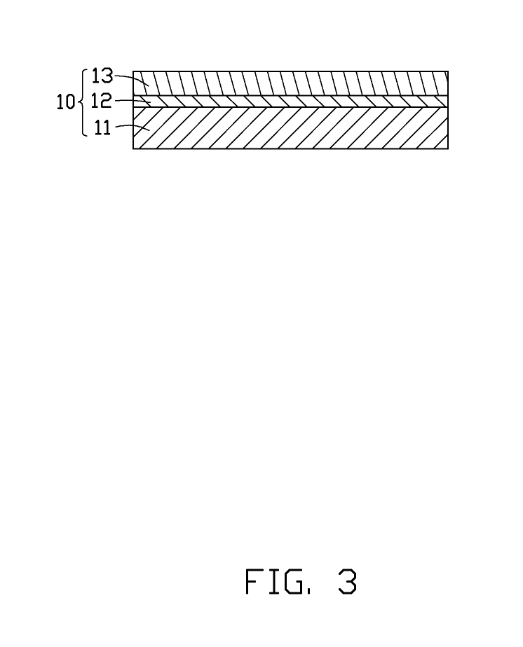

Referring to FIGS. 3-9, the present disclosure provides a method for manufacturing the LED bar module 1 which comprises the following steps:

As show in FIG. 3, the lengthwise base 10 is provided. The lengthwise base 10 has a metal layer 11, a metal circuit layer 13 and an insulated layer 12 between the metal layer 11 and the metal circuit layer 13.

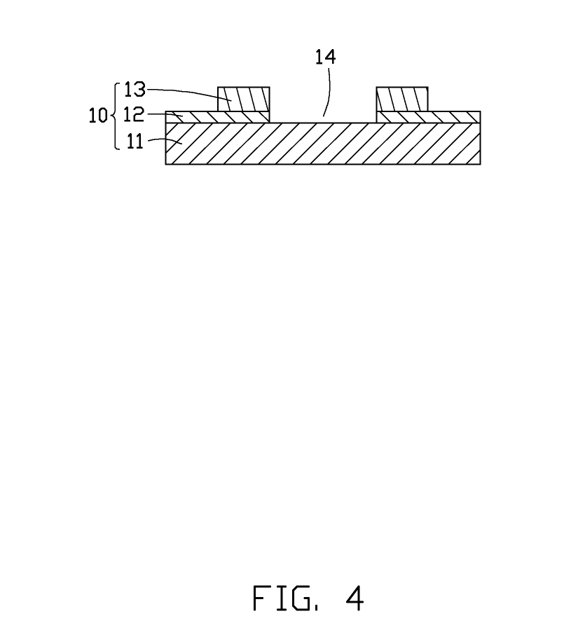

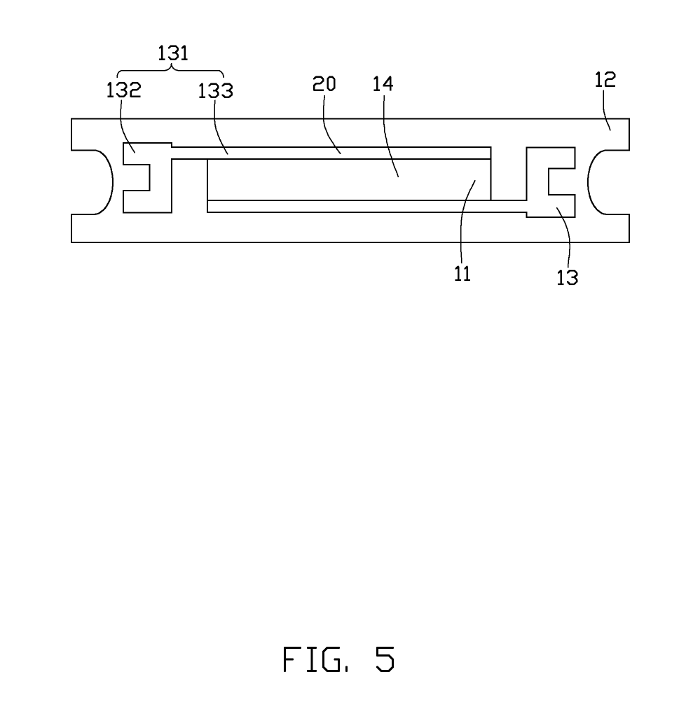

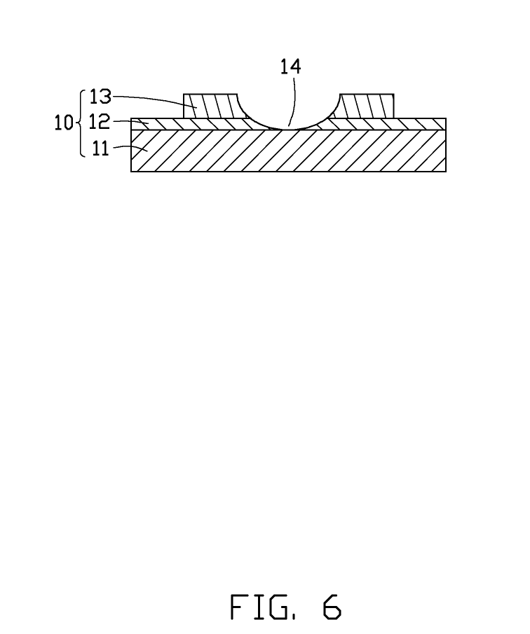

As show in FIGS. 4 and 5, two connecting portions 131 are formed at two opposite sides of the base 10 by etching or laser processing. Each connecting portion 131 includes a U-shaped bonding part 132 and an elongated strip 133 connecting the bonding part 133 and extending from the bonding part 133 to the other bonding part 133 located opposite the bonding part 133. The bonding parts 132 of the two connecting portions 131 are symmetrically located at two opposite ends of the base 10, and the elongated strips 133 of the two connecting portions 131 face and are parallel to each other. The bonding parts 132 are configured for facilitating transmission of electrical power and signals from an external apparatus (not shown) to the LED chips 30 to drive the LED chips 30 to lighten. A rectangular groove 14 is formed between the two strips 133 of the connecting portions 131 by etching or laser processing the metal circuit layer 13 and the insulated layer 12 to expose a part of a top surface of the metal layer 11. Side surfaces (not labeled) of the groove 14 can be perpendicular to the exposed part of top surface of the metal layer 11. Alternatively, the side surfaces of the groove 14 may be curved surfaces, as shown in FIG. 6.

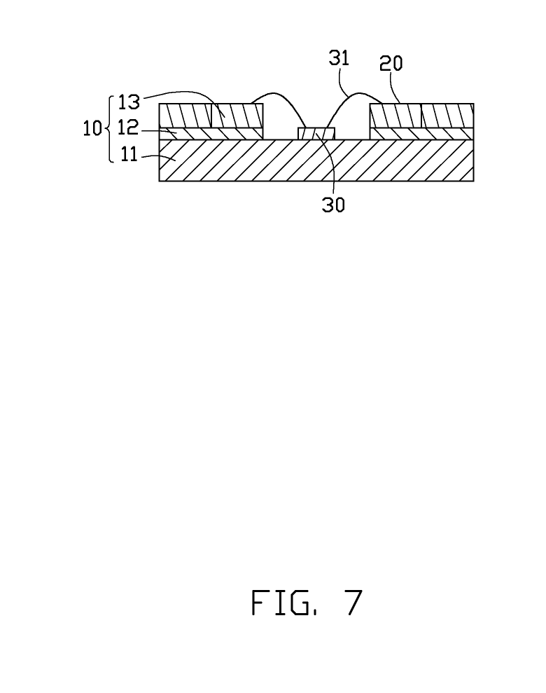

As show in FIG. 7, a number of LED chips 30 are placed in the groove 14 and mounted on the exposed part of the top surface of the metal layer 11. The LED chips 30 are arranged between the two elongated strips 133 of the connecting portions 131 in a juxtaposed manner. Two electrodes (not shown) of each LED chip 30 are respectively connected to the two strips 133 by metal wires 31. Since the metal circuit layer 13 has flat top surface, there is free space for wire bonding the LED chips 30 and the strips 133, whereby manufacturing quality for the LED bar module 1 can be improved.

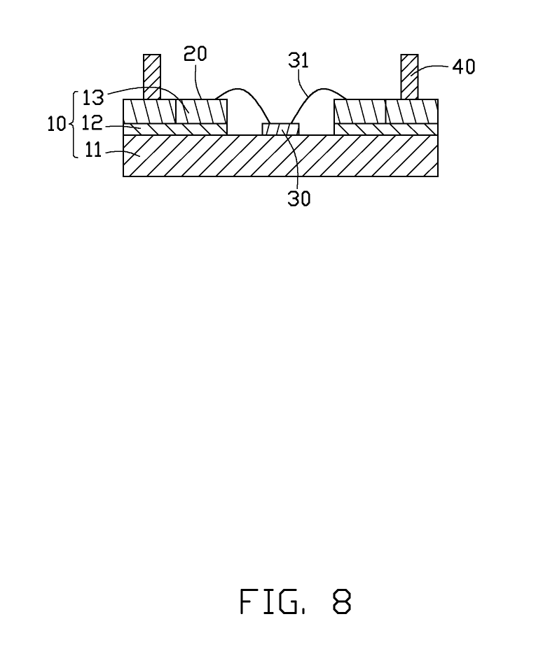

As shown in FIG. 8, a reflecting wall 40 is placed on the metal circuit layer 13 of the base 10. The reflecting wall 40 is rectangular and has four side walls substantially perpendicular to the base 10, for reflecting light from the LED chips 30.

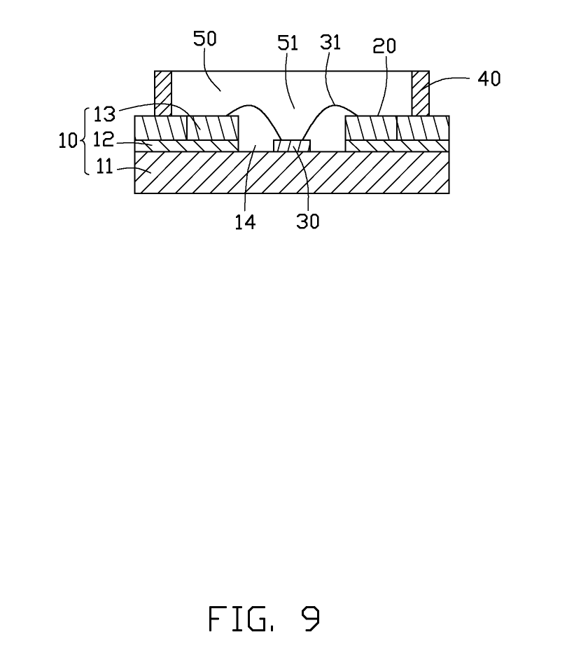

Referring to FIG. 9, an encapsulation 50 is placed in the reflecting wall 40 by glue-dispensing processing, to encapsulate the LED chips 30 and the two strips 133 therein, which are extended within the reflecting wall 40. The encapsulation 50 is then pressed by a mold (not shown) until a top of the encapsulation 50 is coplanar with a top of the reflecting wall 40. In addition, a phosphor 51 can be mixed in the encapsulation 50 to obtain a desired color of light of the LED bar module 1.

As described above, the LED chips 30 are directly contacting the exposed part of the top surface of the metal layer 11 of the base 10, such that heat from the LED chips 30 is effectively dissipated by the metal layer 11 away from the LED chips 30, whereby heat-dissipation efficiency of the LED bar module 1 is optimized and lifespan of the LED chips 30 can be extended. In addition, the metal layer 11 is made of materials with good flexibility, so the LED bar module 1 can be manufactured to having various configuration, making it is possible to applying the LED bar module 1 in back lights or illumination devices.

It is to be understood, however, that even though numerous characteristics and advantages of the disclosure have been set forth in the foregoing description, together with details of the structures and functions of the embodiment(s), the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED bar module, comprising:
a lengthwise base comprising a metal layer, a metal circuit layer, and an insulated layer between the metal layer and the metal circuit layer, the insulated layer defining a groove in a central thereof to expose a part of the metal layer;
a plurality of LED chips placed in the groove and directly contacting the exposed part of the metal layer, the metal circuit layer comprising two connecting portions, the LED chips being located between and electrically connected with the two connecting portions, the LED chips being arranged in a juxtaposed manner with the two connecting portions.

2. The LED bar module of claim 1, wherein the two connecting portions of the circuit layer are located at two opposite sides of the base, each connecting portion comprises a bonding part and an elongated strip connecting the bonding part, the bonding parts of the two connecting portions are symmetrically located at two opposite ends of the base, and the elongated strips of the two connecting portions face and are parallel to each other, the LED chips are arranged between the two elongated strips of the connecting portions.

3. The LED bar module of claim 1, further comprising a reflecting wall located on the metal circuit layer of the base to surround the groove.

4. The LED bar module of claim 3, further comprising an encapsulation filled in the reflecting wall to encapsulate the LED chips therein and parts of the metal circuit layer within the reflecting wall.

5. The LED bar module of claim 3, wherein at least one side surface of the reflecting wall is perpendicular to the base.

6. The LED bar module of claim 1, wherein the metal layer is made of copper.

7. The LED bar module of claim 1, wherein the a thickness of the metal circuit layer is less than that of the metal layer, the thickness of the metal layer ranges from 0.2 mm to 0.3 mm, and the thickness of the metal circuit layer ranges from 0.15 mm to 0.2 mm.

8. An LED bar module, comprising:
a base comprising a metal layer and a metal circuit layer formed on and insulated from the metal layer, the lengthwise base defining a groove through the metal circuit layer;
a plurality of LED chips placed in the groove and directly contacting the metal layer and electrically connecting with the metal circuit layer.

9. The LED bar module of claim 8, wherein the metal circuit layer comprises two opposite connecting portions, each connecting portion comprises a bonding part and an elongated strip connecting the bonding part, the bonding parts of the two connecting portions are symmetrically located at two opposite ends of the base, and the elongated strips of the two connecting portions face each other, the LED chips are arranged between the two elongated strips of the connecting portions.

10. The LED bar module of claim 8, further comprising a reflecting wall located on the metal circuit layer of the base to surround the groove.

11. The LED bar module of claim 10, further comprising an encapsulation filled in the reflecting wall to encapsulate therein the LED chips and parts of metal circuit layer extending within the reflecting wall.

12. The LED bar module of claim 10, wherein at least one side surface of the reflecting wall is perpendicular to the base.

13. The LED bar module of claim 8, wherein the metal layer is made of copper.

14. The LED bar module of claim 8, wherein the a thickness of the metal circuit layer is less than that of the metal layer, the thickness of the metal layer ranges from 0.2 mm to 0.3 mm, and the thickness of the metal circuit layer ranges from 0.15 mm to 0.2 mm.

15. A method for manufacturing an LED bar module, comprising:
providing a lengthwise base, the base comprising a metal layer, a metal circuit layer, and an insulated layer between the metal layer and the metal circuit layer;
forming a groove in a central of the insulated layer to expose a part of the metal layer;
providing a plurality of LED chips in the groove and mounting the plurality of LEDs chips on the exposed part of the metal layer;
wiring bonding the LED chips with the metal circuit layer;
providing a reflecting wall on the metal circuit layer to surround the LED chips; and
providing an encapsulation in the reflecting wall to encapsulate therein the LED chips and parts of the metal circuit layer.
